(19) United States
(12) Patent Application Publication
(10) Pub. No.: US 2025/0062725 A1
(43) Pub. Date: Feb. 20, 2025

(54) HIGH LINEARITY POWER AMPLIFIER

(71) Applicant: Skyworks Solutions, Inc., Irvine, CA (US)

(72) Inventors: Yu Zhu, Wellesley, MA (US); Oleksiy Klimashov, Burlington, MA (US); Dylan Charles Bartle, Arlington, MA (US); Paul T. DiCarlo, Marlborough, MA (US)

(21) Appl. No.: 18/792,775

(22) Filed: Aug. 2, 2024

Related U.S. Application Data
(60) Provisional application No. 63/532,759, filed on Aug. 15, 2023.

(51) Int. Cl. H03F 1/32; H03F 3/24

(52) U.S. Cl. CPC H03F 1/32; H03F 3/245; H03F 2200/451

(57) ABSTRACT

Aspects of the disclosure include a method of biasing a power amplifier including applying a drain voltage to a drain of the power amplifier, determining, based on the drain voltage, a range of acceptable gate voltages to apply to the power amplifier, determining a first optimal gate voltage within the range of acceptable gate voltages, determining a second optimal gate voltage within the range of acceptable gate voltages, selecting one of the first optimal gate voltage or the second optimal gate voltage to apply to the power amplifier, and applying either the first optimal gate voltage or the second optimal gate voltage to the gate of the power amplifier.

### CROSS-REFERENCE TO RELATED APPLICATIONS

This application claims priority under 35 U.S.C. § 119 (e) to U.S. Provisional Application Ser. No. 63/532,759, titled “HIGH LINEARITY POWER AMPLIFIER,” filed on Aug. 15, 2023, which is hereby incorporated by reference in its entirety.

### BACKGROUND

### 1. Field of the Disclosure

At least one example in accordance with the present disclosure relates generally to power amplifiers.

### 2. Discussion of Related Art

Power amplifiers amplify signals. A power amplifier receives an input signal, amplifies the input signal to produce an amplified output signal, and provides the amplified output signal to an output. A power amplifier may amplify the input signal according to a gain value, which specifies an amount by which the input signal is to be amplified.

### SUMMARY

According to at least one aspect of the present disclosure, a method of biasing a power amplifier is provided comprising applying a drain voltage to a drain of the power amplifier, determining, based on the drain voltage, a range of acceptable gate voltages to apply to the power amplifier, determining a first optimal gate voltage within the range of acceptable gate voltages, determining a second optimal gate voltage within the range of acceptable gate voltages, selecting one of the first optimal gate voltage or the second optimal gate voltage to apply to the power amplifier, and applying either the first optimal gate voltage or the second optimal gate voltage to the gate of the power amplifier.

In at least one example, at the first optimal gate voltage and the second optimal gate voltage, a third-order derivative of a transconductance of the power amplifier is zero. In at least one example, the first optimal gate voltage and the second optimal gate voltage each correspond to a zero-crossing of the third-order derivative of the transconductance of the power amplifier. In at least one example, the first optimal gate voltage and the second optimal gate voltage correspond to the only zero-crossings of the third-order derivative of the transconductance of the power amplifier within the range of acceptable gate voltages. In at least one example, the first optimal gate voltage or the second optimal gate voltage corresponds to a drain-voltage-independent minimum of a third-order intermodulation point.

In at least one example, the first optimal gate voltage or the second optimal gate voltage corresponds to a drain-voltage-dependent minimum of a third-order intermodulation point. In at least one example, the first optimal gate voltage corresponds to a drain-voltage-independent first local minimum of a third-order intermodulation point and the second optimal gate voltage corresponds to a drain-voltage-dependent second local minimum of the third-order intermodulation point. In at least one example, the first local minimum and the second local minimum correspond to the two local minima within the range of acceptable gate voltages.

In at least one example, the first optimal gate voltage corresponds to a drain-voltage-independent minimum of a third-order intermodulation point and corresponds to a minimum drain current through the drain of the power amplifier. In at least one example, the second optimal gate voltage corresponds to a drain-voltage-dependent minimum of the third-order intermodulation point and corresponds to a minimum drain voltage applied to the drain of the power amplifier. In at least one example, the second optimal gate voltage corresponds to a drain-voltage-independent minimum of the third-order intermodulation point and corresponds to a minimum drain voltage applied to the drain of the power amplifier.

According to at least one example of the disclosure, a power amplifier is comprising a power amplifier having a gate and a drain, a gate bias node coupled to the gate, a drain bias node coupled to the drain, and control circuitry configured to provide a drain voltage to the drain bias node, determine, based on the drain voltage, a range of acceptable gate voltages to apply to the gate bias node, determine a first optimal gate voltage within the range of acceptable gate voltages, determine a second optimal gate voltage within the range of acceptable gate voltages, select one of the first optimal gate voltage or the second optimal gate voltage to apply to the gate bias node, and provide either the first optimal gate voltage or the second optimal gate voltage to the gate bias node.

In at least one example, at the first optimal gate voltage and the second optimal gate voltage, a third-order derivative of a transconductance of the power amplifier is zero. In at least one example, the first optimal gate voltage and the second optimal gate voltage each correspond to a zero-crossing of the third-order derivative of the transconductance of the power amplifier. In at least one example, the first optimal gate voltage and the second optimal gate voltage correspond to the only zero-crossings of the third-order derivative of the transconductance of the power amplifier within the range of acceptable gate voltages.

In at least one example, the first optimal gate voltage or the second optimal gate voltage corresponds to a drain-voltage-independent minimum of a third-order intermodulation point. In at least one example, the first optimal gate voltage or the second optimal gate voltage corresponds to a drain-voltage-dependent minimum of a third-order intermodulation point. In at least one example, the first optimal gate voltage corresponds to a drain-voltage-independent first local minimum of a third-order intermodulation point and the second optimal gate voltage corresponds to a drain-voltage-dependent second local minimum of the third-order intermodulation point. In at least one example, the first local minimum and the second local minimum correspond to the two local minima within the range of acceptable gate voltages. In at least one example, the first optimal gate voltage corresponds to a drain-voltage-independent minimum of a third-order intermodulation point and corresponds to a minimum drain current through the drain of the power amplifier.

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a block diagram of a wireless device according to an example;

FIG. 2 illustrates a schematic diagram of a power amplifier according to an example;

FIG. 3A illustrates a graph of a drain current as a function of gate voltage according to an example;

FIG. 3B illustrates a graph of a transconductance as a function of gate voltage according to an example;

FIG. 4 illustrates a graph including a trace which illustrates the third-order derivative of a transconductance according to an example;

FIG. 5 illustrates a graph depicting third-order intermodulation (IM3) values for a variety of drain voltages according to an example;

FIG. 6 illustrates a graph of drain currents as a function of drain voltage according to an example;

FIG. 7 illustrates a graph of third-order intercept points (IP3) according to an example; and

FIG. 8 illustrates a process of operating a power amplifier according to an example.

### DETAILED DESCRIPTION

As discussed above, power amplifiers may be used to amplify input signals pursuant to a gain value. An ideal power amplifier may exhibit a perfectly linear gain, that is, an amplifier with a constant gain independent of the magnitude of the input signal. In a nonlinear device, the output signal may be distorted relative to the input signal. One measure of this nonlinear distortion includes third-order intermodulation (IM3). It may be advantageous to minimize the IM3 value to improve linearity of the power amplifier.

The IM3 value may be adjusted by varying certain parameters of the power amplifier. For example, a power amplifier implementing a depletion-mode metal-oxide-semiconductor field-effect transistor (DFET) may be characterized by several controllable parameters including, for example, drain current, gate voltage, drain voltage, and so forth. While these parameters may be modified to minimize IM3, such modifications may be limited by other design constraints. For example, while increasing a gate voltage may lower IM3, increasing the gate voltage may also disadvantageously increase power consumption. In another example, while increasing drain voltage may lower IM3, increasing the drain voltage may also risk disadvantageously exceeding the breakdown voltage of the DFET. Accordingly, selecting an IM3 value may involve a consideration of multiple design constraints.

Examples of the disclosure provide power amplifiers with multiple local optimal values for bias parameters. For example, multiple local optimal values for gate voltages may be identified for a given drain voltage. Accordingly, for a given drain voltage, multiple optimal values for a gate voltage may be available to bias an amplifier device, such as a DFET. These optimal values may satisfy all design constraints while minimizing IM3.

Examples of the disclosure may be implemented in connection with power amplifiers in many types of electronic devices or systems, such as consumer electronics (for example, televisions, gaming consoles, personal computers, tablet computers, desktop computers, and so forth), vehicles, communication equipment, electrical-utility equipment, or other devices or systems having power amplifiers. For purposes of explanation, examples are provided with reference to wireless devices. For example, the wireless device may include a mobile telephone, such as a smartphone. However, it is to be appreciated that the principles of the disclosure are more broadly applicable to power amplifiers in any of various devices or systems, and that wireless devices are described for purposes of example only.

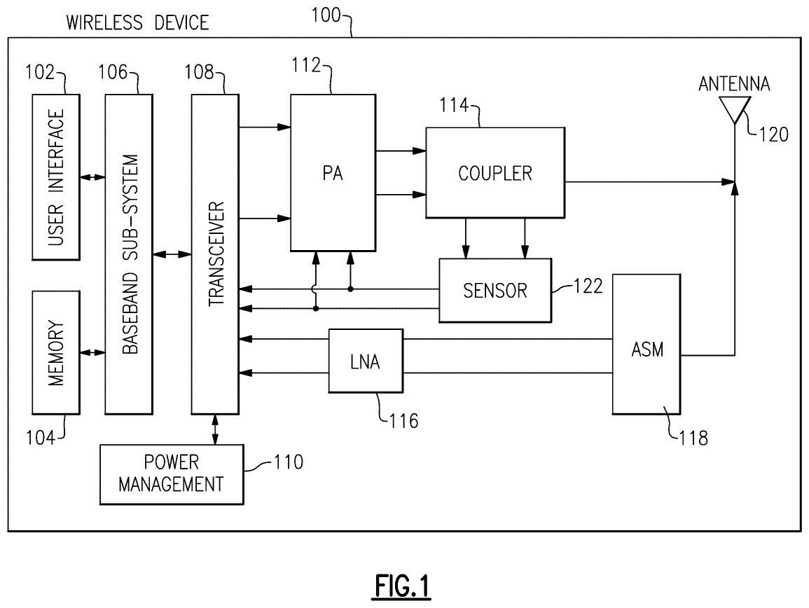

FIG. 1 illustrates a block diagram of a wireless device 100 according to an example. The wireless device 100 can be a cellular phone, smart phone, tablet, modem, communication network or any other portable or non-portable device configured for voice and/or data communication. The implementation shown in FIG. 1 is exemplary and non-limiting. The wireless device 100 includes a user interface 102, memory and/or storage 104, a baseband sub-system 106, a transceiver 108, a power-management system 110, a power-amplifier (PA) module 112, a coupler 114, a low-noise amplifier (LNA) 116, a switching circuit 118 (also referred to as an antenna switch module [ASM]), an antenna 120, and at least one sensor 122.

The antenna 120 is configured to transmit and/or receive one or more signals, such that the wireless device 100 may communicate with one or more external devices via the antenna 120. The transceiver 108 is configured to generate signals for transmission and/or to process received signals. In some embodiments, transmission and reception functionalities can be implemented in separate components (for example, a transmit module and a receiving module) or be implemented in the same module.

Signals generated for transmission are provided from the transceiver 108 to the PA module 112, which amplifies the generated signals from the transceiver 108. As will be appreciated by those skilled in the art, the PA module 112 can include one or more power amplifiers. The PA module 112 can be used to amplify a wide variety of radio-frequency (RF) or other frequency-band transmission signals. For example, the PA module 112 can receive an enable signal that can be used to pulse the output of the power amplifier to aid in transmitting a wireless local-area-network (WLAN) signal or any other suitable pulsed signal. The PA module 112 can be configured to amplify any of a variety of types of signal, including, for example, 5G signals, a Global System for Mobile (GSM) signal, a code-division multiple-access (CDMA) signal, a W-CDMA signal, a Long-Term-Evolution (LTE) signal, or an EDGE signal. In certain embodiments, the PA module 112 and associated components including switches and the like can be fabricated on GaAs substrates using, for example, pHEMT or BiFET transistors, or on a silicon substrate using CMOS transistors. The wireless device 100 also includes the LNA 116, which may include one or more power amplifiers configured to amplify received signals in a similar or different manner as power amplifier(s) of the PA module 112.

The wireless device 100 also includes the switching circuit 118, which is configured to switch between different bands and/or modes. For example, the switching circuit 118 may be configured to couple the LNA 116 to the antenna 120 in a receive mode of operation and to decouple the LNA 116 from the antenna 120 in a transmit mode of operation. Similarly, the PA module 112 is coupled to the antenna 120 such that signals provided to the antenna 120 from the PA module 112 in the transmit mode of operation bypass the receive path (and switching circuit 118) of the wireless device 100.

Accordingly, in certain embodiments the antenna 120 can both receive signals that are provided to the transceiver 108 via the switching circuit 118 and the LNA 116 and also transmit signals from the wireless device 100 via the transceiver 108, the PA module 112, and the coupler 114. However, in other examples multiple antennas can be used for different modes of operation.

The power-management system 110 is connected to the transceiver 108 and is configured to manage the power for the operation of the wireless device 100. The power-management system 110 can also control the operation of the wireless device 100, such as by controlling components of power amplifier(s) of the PA module 112 and/or LNA 116. Controlling components of the PA module 112 may include, for example, selecting and/or providing bias signals to power-amplification devices (for example, FETs) within the PA module 112. The power-management system 110 can include, or can be connected to, a battery that supplies power for the various components of the wireless device 100. The power-management system 110 can further include one or more processors or controllers that can control the transmission of signals and can also configure components of the wireless device 100 based upon the frequency of the signals being transmitted or received, for example. In addition, the processor(s) or controller(s) of the power-management system 110 may provide control signals to actuate switches, tune components, or otherwise configure components of the wireless device 100, such as components of the PA module 112 and/or LNA 116, as discussed below. In at least one embodiment, the processor(s) or controller(s) of the power-management system 110 can also provide control signals to control the switching circuit 118 to operate in the transmit or receive mode.

In one embodiment, the baseband sub-system 106 is connected to the user interface 102 to facilitate various input and output of voice and/or data provided to and received from the user. The baseband sub-system 106 can also be connected to the memory and/or storage 104 which is configured to store data and/or instructions to facilitate the operation of the wireless device, and/or to provide storage of information for the user.

The wireless device 100 also includes the coupler 114 having one or more coupler sections for measuring transmitted power signals from the PA module 112 and for providing one or more coupled signals to at least one sensor 122. In some examples, the coupler 114 is further configured to measure transmitted power signals from the LNA 116. In various examples, the wireless device 100 includes one or more couplers in addition to, or in lieu of, the coupler 114 to measure transmitted power signals from the LNA 116.

The at least one sensor 122 can in turn send information to the transceiver 108, power-management system 110, and/or directly to the PA module 112 and/or LNA 116 as feedback for making adjustments to regulate the power level of the PA module 112 and/or LNA 116. In this way the coupler 114 can be used to boost/decrease the power of a transmission signal having a relatively low/high power. It will be appreciated, however, that the coupler 114 can be used in a variety of other implementations.

For example, in certain embodiments in which the wireless device 100 is a mobile phone having a time division multiple access (TDMA) architecture, the coupler 114 can advantageously manage the amplification of an RF transmitted power signal from the PA module 112 and/or LNA 116. In a mobile phone having a TDMA architecture, such as those found in GSM, CDMA, and W-CDMA systems, the PA module 112 can be used to shift power envelopes up and down within prescribed limits of power versus time. For instance, a particular mobile phone can be assigned a transmission time slot for a particular frequency channel. In this case the PA module 112 and/or LNA 116 can be employed to aid in regulating the power level one or more RF power signals over time, so as to prevent signal interference from transmission during an assigned receive time slot and to reduce power consumption. In such systems, the coupler 114 can be used to measure the power of a power-amplifier output signal to aid in controlling the PA module 112 and/or LNA 116, as discussed above.

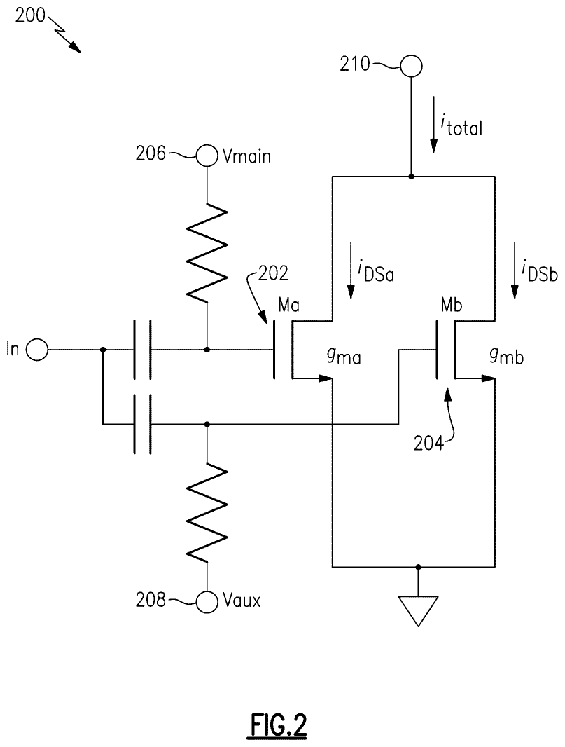

The PA module 112 may be implemented according to any of various topologies. For example, FIG. 2 illustrates a schematic diagram of a power amplifier 200 according to an example. The power amplifier 200 includes a first device 202 coupled in parallel with a second device 204. Each of the devices 202, 204 may be the same type of device (for example, a metal-oxide-semiconductor field-effect transistor [MOSFET]). However, each of the devices 202, 204 may operate differently based on received bias signals. For example, the first device 202 may be a main amplifying device operated as a DFET, and the second device 204 may be an auxiliary amplifying device operated as an enhancement-mode MOSFET (EFET).

Modifying certain bias parameters of the devices 202, 204 may affect various other properties of the devices 202, 204. Bias parameters may include, for example, a gate voltage applied to the gate of the first device 202 via a first gate bias node 206, a gate voltage applied to the gate of the second device 204 via a second gate bias node 208, a drain voltage applied to the devices 202, 204 via a drain bias node 210, and so forth. Bias signals may be applied by a component of the device 100, such as the power-management system 110, configured to output a signal of a desired voltage. Using the first device 202 as an example, modifying the drain voltage applied to the drain of the first device 202 via the drain bias node 210 may modify parameters such as the drain current (Id) and the transconductance (gm) of the first device 202.

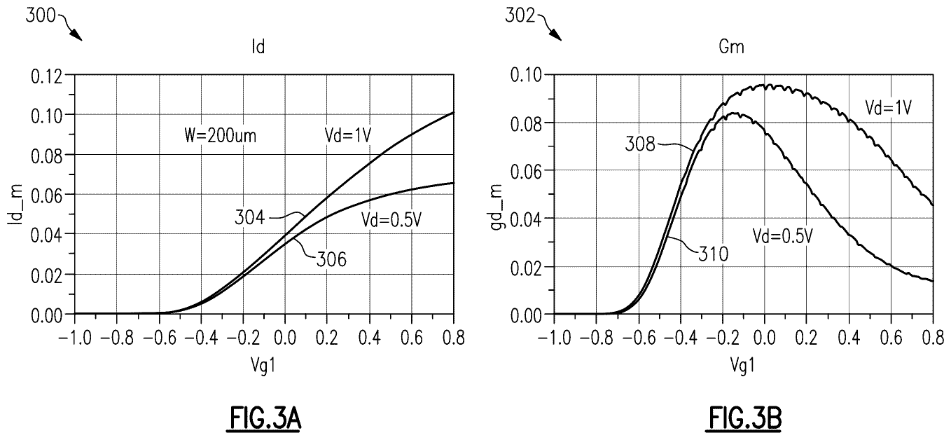

For example, FIG. 3A illustrates a graph 300 of a drain current as a function of gate voltage according to an example, and FIG. 3B illustrates a graph 302 of a transconductance as a function of gate voltage according to an example. The graph 300 includes a first trace 304 of a drain current corresponding to a first drain voltage (for example, 1V) and a second trace 306 of a drain current corresponding to a second drain voltage lower than the first drain voltage (for example, 0.5 V). The graph 302 includes a third trace 308 of a transconductance corresponding to the first drain voltage and a fourth trace 310 of a transconductance corresponding to the second drain voltage.

As illustrated by the traces 304-310, the lower drain voltage of the traces 306, 310 corresponds to more stable operation. For example, the second trace 306 reaches a stable value before the first trace 304, and the fourth trace 310 peaks and decreases sooner than the third trace 308.

Each transition in the traces 308, 310 from a concave-up orientation to a concave-down orientation, or vice versa, may correspond to a point at which the third-order derivative of the transconductance (gm3) is at a minimum. Minimizing the third-order derivative of the transconductance may correspond to minimizing the IM3 value. Accordingly, it may be advantageous to operate the first device 202 at bias points corresponding to the inflection points of the transconductance traces. However, as illustrated by the traces 308, 310, increasing the drain voltage may also increase the inflection point of the transconductance traces along the gate-voltage axis. It may not be feasible to operate the first device 202 at such high gate voltages as the drain voltage is increased due to the increased power consumption associated with higher gate voltages. Accordingly, by lowering the drain voltage, the inflection points may be lowered to more feasible levels.

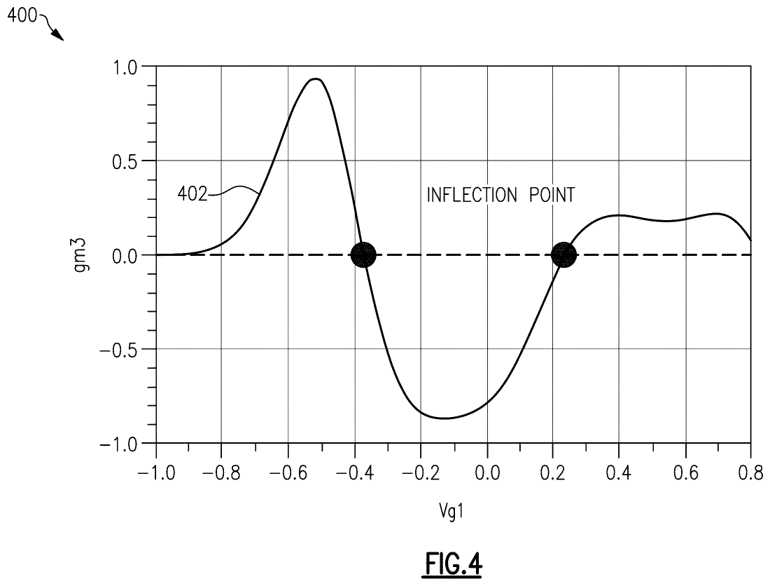

FIG. 4 illustrates a graph 400 including a trace 402 which illustrates the third-order derivative of the fourth trace 310. The trace 402 includes zero-crossings at a gate voltage of approximately-0.4 V and at a gate voltage of approximately 0.2 V. Accordingly, at the drain voltage of FIG. 4 (for example, 0.5 V), biasing the first device 202 with a gate voltage of approximately-0.4 V or 0.2 V may advantageously minimize the IM3 of the first device 202. Although such zero-crossings may exist at higher drain voltages as well, increasing the drain voltage may increase the zero-crossings of the third-order derivative as discussed above with respect to the third trace 308. Increasing the zero-crossings of the third-order derivative may be disadvantageous at least because such zero-crossings may correspond to higher gate voltages and, thus, higher power-consumption values. At higher drain voltages, therefore, the gate voltages which are optimal from an IM3-minimization perspective may be poor from a power-consumption perspective.

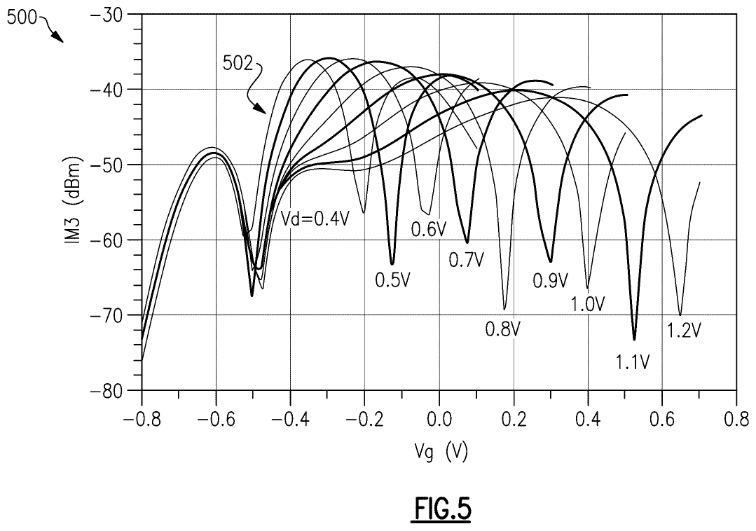

For example, FIG. 5 illustrates a graph 500 depicting IM3 values for a variety of drain voltages according to an example. The graph 500 includes several traces 502, each corresponding to an IM3 value as a function of gate voltage for a respective drain voltage. Each of the traces 502 exhibits a first local minimum around a gate voltage of −0.5 V, which is largely independent of drain voltage. Each of the traces 502 also exhibits a second local minimum which is related to drain voltage. For example, at a drain voltage of 0.4 V, a second local minimum occurs at a gate voltage of around-0.2 V. Similarly, at a drain voltage of 1 V, a second local minimum occurs at a gate voltage of around 0.4 V.

Accordingly, when operating at a particular drain voltage, at least two local IM3 minima may exist at which to bias the gate voltage. A first local minimum may be independent of the drain voltage, and a second local minimum may be dependent on the drain voltage. Additional minima may exist, but may not comply with other design considerations. For example, as illustrated by the traces 502, IM3 may be minimized at a gate voltage of −0.8 V for various drain voltages. However, such a large gate-voltage magnitude may correspond to an unacceptably high current and power consumption. The two local minima discussed above may be more optimal bias points, because they correspond to gate voltages at which IM3 can be minimized without substantial power consumption. As discussed in greater detail below, the two local minima may be defined at least in part by corresponding to the local minima of gate voltages within a certain range of acceptable values.

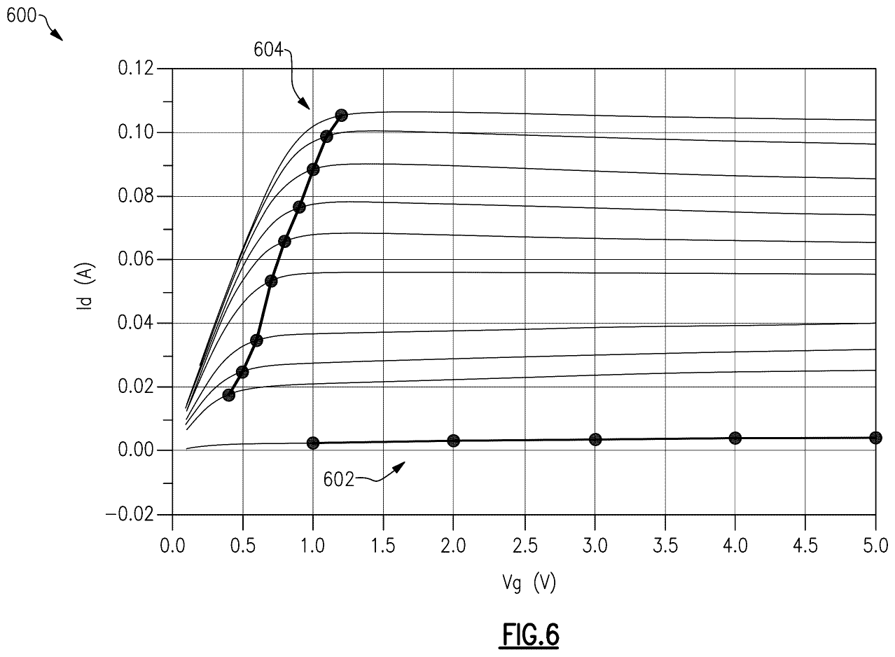

FIG. 6 illustrates a graph 600 of drain currents as a function of drain voltage according to an example. The graph 600 includes several traces each illustrating a respective drain current as a function of drain voltage. A first group of data points 602 illustrates drain currents corresponding to the first local minimum of IM3 values in FIG. 5, that is, the minima that are independent of drain voltage. As illustrated by the first group of data points 602, the drain current changes very little for large shifts in drain voltage. In addition to varying little, the drain-current values are relatively small. Conversely, a second group of data points 604 illustrates drain currents corresponding to the second local minimum of IM3 values in FIG. 5, that is, the minima that are dependent on drain voltage. As illustrated by the second group of data points 604, the drain current changes relatively significantly for small changes in drain voltage. The drain-voltage values corresponding to the second group of data points 604 are relatively small.

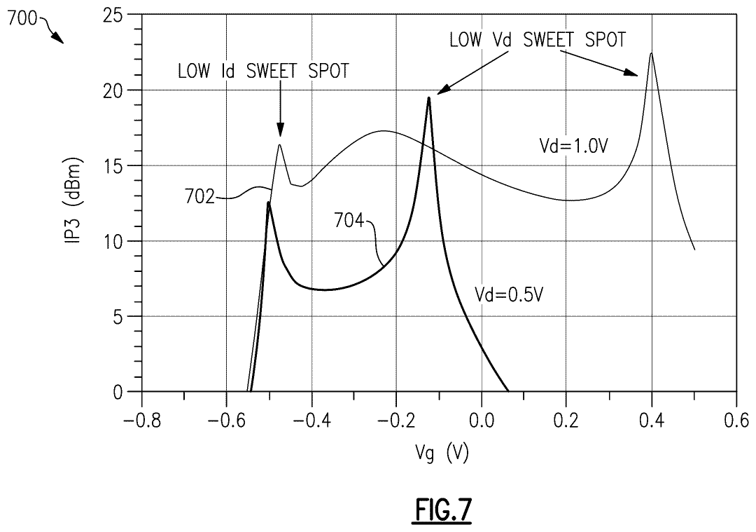

FIG. 7 illustrates a graph 700 of third-order intercept points (IP3) according to an example. The graph 700 includes a first trace 702 corresponding to an IP3 value as a function of gate voltage for the first drain voltage (for example, 1 V) and a second trace 704 corresponding to an IP3 value as a function of gate voltage for the second drain voltage (for example, 0.5 V). The traces 702, 704 exhibit a first local maximum around a gate voltage of −0.5 V, which may correspond to a drain-voltage-independent voltage maximum. The drain-voltage-independent voltage maximum, in turn, may correspond to a low drain current as discussed above. The first trace 702 exhibits a second local maximum around a gate voltage of 0.4 V, which may correspond to a first drain-voltage-dependent IP3 maximum. The first drain-voltage-dependent IP3 maximum may correspond to a low drain voltage as discussed above. The second trace 704 exhibits a second local maximum around a gate voltage of −0.1 V, which may correspond to a second drain-voltage-dependent IP3 maximum. The second drain-voltage-dependent IP3 maximum may also correspond to a low drain voltage as discussed above.

In light of the foregoing, multiple gate-voltage bias points may be feasibly implemented at certain drain voltages. For example, at low drain voltages, multiple gate-voltage bias points at which IM3 is locally minimized may exist. At higher drain voltages (for example on the order of 3-5 V), only a single gate-voltage point may both provide a local IM3 minimum while staying within power-consumption design constraints. Accordingly, operating at lower drain voltages enables a power amplifier to be biased at any of several different optimal gate-voltage bias points.

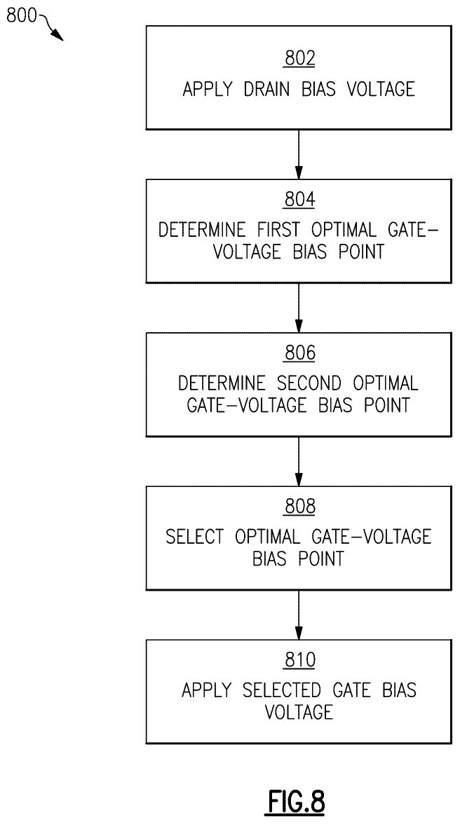

FIG. 8 illustrates a process 800 of operating a power amplifier according to an example. For example, the process 800 may be executed to operate the power amplifier 200. In particular, the process 800 may be executed to bias the device 202 in the power amplifier 200. Aspects of the process 800 may be executed at least in part by the power-management system 110. For example, the power-management system 110 may include one or more processors, controllers, and/or other control circuitry to manage operation of the power amplifier 200.

At act 802, a drain bias voltage is applied to the drain of the device 202. The drain bias voltage may be applied by circuitry of the wireless device 100, such as the power-management system 110. The drain bias voltage may be selected in accordance with design constraints. For example, certain low-power devices may specify a drain voltage of no greater than 1 V. Accordingly, the drain bias voltage may be selected and applied based on the design constraints of the particular application of the device 202.

At act 804, the power-management system 110 determines a first optimal gate-voltage bias point. The first optimal gate-voltage bias point may correspond to a first local IM3 minimum for gate voltages at the drain bias voltage determined at act 802. The first optimal gate-voltage bias point may be identified within a range of permissible gate voltages. The range of permissible gate voltages may be specified by design constraints such as power-consumption limitations. For example, gate voltages may be limited within-0.8 V and 0.8 V in some examples. Act 804 may thus include determining a first gate voltage within the permissible range of gate voltages that yields a first local IM3 minimum. The first local IM3 minimum may be a drain-voltage-independent minimum.

At act 806, the power-management system 110 determines a second optimal gate-voltage bias point. The second optimal gate-voltage bias point may correspond to a second local IM3 minimum for gate voltages at the drain bias voltage determined at act 802, and within the range of permissible gate voltages discussed above with respect to act 804. Because the drain voltage may be relatively low in this example as discussed above, there may be multiple local IM3 minimums within the range of permissible gate voltages. As discussed above, for higher drain voltages (for example, 3-5 V), a second local IM3 minimum may correspond to a gate voltage that is well beyond an acceptable upper limit for the gate voltage to be biased at. Act 806 may thus include determining a second local IM3 minimum within the range of permissible gate voltages, where the second local IM3 minimum may be a drain-voltage-dependent minimum.

At act 808, the power-management system 110 selects one of the optimal gate-voltage bias points at which to bias the device 202. The selection may be based on any of various design considerations. For example, the power-management system 110 may select the lower of the two gate voltages, which may reduce power consumption. In another example, the power-management system 110 may select the gate voltage corresponding to a lower IM3 value. In still other examples, the power-management system 110 may make the selection based on additional or different factors, and/or a combination thereof.

At act 810, the power-management system 110 applies the gate voltage selected at act 808 to the first device 202. For example, the power-management system 110 may apply the selected gate voltage via the first gate bias node 206 of FIG. 2. The first device 202 may thereby be biased at a desired value.

Accordingly, the first device 202 may be biased at any of several optimal bias points. The optimal bias points may correspond to optimal gate-voltage values within an acceptable range of gate voltages for a given drain-voltage value. In various examples, gate-voltage bias points may have multiple local minima within a range of acceptable gate-voltage values only at sufficiently low drain-voltage values. Accordingly, in various examples multiple optimal gate-voltage bias points may be identified for low-drain-voltage applications in power amplifiers. In some examples, the first device 202 may include a DFET. In other examples, the first device 202 may include a switching device other than a DFET, such as an EFET, BJT, and so forth.

Various controllers, such as controllers within the power-management system 110, may execute various operations discussed above. Using data stored in associated memory and/or storage, the controller also executes one or more instructions stored on one or more non-transitory computer-readable media, which the controller may include and/or be coupled to, that may result in manipulated data. In some examples, the controller may include one or more processors or other types of controllers. In one example, the controller is or includes at least one processor. In another example, the controller performs at least a portion of the operations discussed above using an application-specific integrated circuit tailored to perform particular operations in addition to, or in lieu of, a processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

1. A method of biasing a power amplifier comprising:
applying a drain voltage to a drain of the power amplifier;
determining, based on the drain voltage, a range of acceptable gate voltages to apply to the power amplifier;
determining a first optimal gate voltage within the range of acceptable gate voltages;
determining a second optimal gate voltage within the range of acceptable gate voltages;
selecting one of the first optimal gate voltage or the second optimal gate voltage to apply to the power amplifier; and
applying either the first optimal gate voltage or the second optimal gate voltage to the gate of the power amplifier.

2. The method of claim 1 wherein at the first optimal gate voltage and the second optimal gate voltage, a third-order derivative of a transconductance of the power amplifier is zero.

3. The method of claim 2 wherein the first optimal gate voltage and the second optimal gate voltage each correspond to a zero-crossing of the third-order derivative of the transconductance of the power amplifier.

4. The method of claim 3 wherein the first optimal gate voltage and the second optimal gate voltage correspond to the only zero-crossings of the third-order derivative of the transconductance of the power amplifier within the range of acceptable gate voltages.

5. The method of claim 1 wherein the first optimal gate voltage or the second optimal gate voltage corresponds to a drain-voltage-independent minimum of a third-order intermodulation point.

6. The method of claim 1 wherein the first optimal gate voltage or the second optimal gate voltage corresponds to a drain-voltage-dependent minimum of a third-order intermodulation point.

7. The method of claim 1 wherein the first optimal gate voltage corresponds to a drain-voltage-independent first local minimum of a third-order intermodulation point and the second optimal gate voltage corresponds to a drain-voltage-dependent second local minimum of the third-order intermodulation point.

8. The method of claim 7 wherein the first local minimum and the second local minimum correspond to the two local minima within the range of acceptable gate voltages.

9. The method of claim 1 wherein the first optimal gate voltage corresponds to a drain-voltage-independent minimum of a third-order intermodulation point and corresponds to a minimum drain current through the drain of the power amplifier.

10. The method of claim 9 wherein the second optimal gate voltage corresponds to a drain-voltage-dependent minimum of the third-order intermodulation point and corresponds to a minimum drain voltage applied to the drain of the power amplifier.

11. The method of claim 1 wherein the second optimal gate voltage corresponds to a drain-voltage-independent minimum of the third-order intermodulation point and corresponds to a minimum drain voltage applied to the drain of the power amplifier.

12. A power amplifier comprising:
a power amplifier having a gate and a drain;
a gate bias node coupled to the gate;
a drain bias node coupled to the drain; and
control circuitry configured to:
provide a drain voltage to the drain bias node;
determine, based on the drain voltage, a range of acceptable gate voltages to apply to the gate bias node;
determine a first optimal gate voltage within the range of acceptable gate voltages;
determine a second optimal gate voltage within the range of acceptable gate voltages;
select one of the first optimal gate voltage or the second optimal gate voltage to apply to the gate bias node; and
provide either the first optimal gate voltage or the second optimal gate voltage to the gate bias node.

13. The power amplifier of claim 12 wherein at the first optimal gate voltage and the second optimal gate voltage, a third-order derivative of a transconductance of the power amplifier is zero.

14. The power amplifier of claim 13 wherein the first optimal gate voltage and the second optimal gate voltage each correspond to a zero-crossing of the third-order derivative of the transconductance of the power amplifier.

15. The power amplifier of claim 14 wherein the first optimal gate voltage and the second optimal gate voltage correspond to the only zero-crossings of the third-order derivative of the transconductance of the power amplifier within the range of acceptable gate voltages.

16. The power amplifier of claim 12 wherein the first optimal gate voltage or the second optimal gate voltage corresponds to a drain-voltage-independent minimum of a third-order intermodulation point.

17. The power amplifier of claim 12 wherein the first optimal gate voltage or the second optimal gate voltage corresponds to a drain-voltage-dependent minimum of a third-order intermodulation point.

18. The power amplifier of claim 12 wherein the first optimal gate voltage corresponds to a drain-voltage-independent first local minimum of a third-order intermodulation point and the second optimal gate voltage corresponds to a drain-voltage-dependent second local minimum of the third-order intermodulation point.

19. The power amplifier of claim 18 wherein the first local minimum and the second local minimum correspond to the two local minima within the range of acceptable gate voltages.

20. The power amplifier of claim 12 wherein the first optimal gate voltage corresponds to a drain-voltage-independent minimum of a third-order intermodulation point and corresponds to a minimum drain current through the drain of the power amplifier.
